(19) United States
(12) Patent Application Publication
(10) Pub. No.: US 2013/0134514 A1
(43) Pub. Date: May 30, 2013

(54) THIN FILM TRANSISTOR AND METHOD FOR FABRICATING THE SAME

(71) Applicant: Hsi-Ming Chang, Taoyuan County (TW)

(72) Inventor: Hsi-Ming Chang, Taoyuan County (TW)

(73) Assignee: CHUNGHWA PICTURE TUBES, LTD., Taoyuan (TW)

(21) Appl. No.: 13/366,267

(22) Filed: Feb. 4, 2012

(30) Foreign Application Priority Data
Nov. 25, 2011 (TW) 100143348

(51) Int. Cl. H01L 27/12; H01L 21/336

(52) U.S. Cl. 257/347; 438/158; 257/E29.273; 257/E27.112; 257/E21.409

(57) ABSTRACT

A thin film transistor and a fabricating method thereof are provided. The thin film transistor includes a gate, a gate insulator, an oxide semiconductor layer, a source, a drain, and a light barrier. The gate insulator covers the gate. The oxide semiconductor layer is disposed on the gate insulator and located above the gate. The source and the drain are disposed on parts of the oxide semiconductor layer. The light barrier is located above the oxide semiconductor layer and includes a first insulator, an ultraviolet shielding layer, and a second insulator. The first insulator is disposed above the oxide semiconductor layer. The ultraviolet shielding layer is disposed on the first insulator. The second insulator is disposed on the ultraviolet shielding layer.

### CROSS-REFERENCE TO RELATED APPLICATION

This application claims the priority benefit of Taiwan application serial no. 100143348, filed on Nov. 25, 2011. The entirety of the above-mentioned patent application is hereby incorporated by reference herein and made a part of this specification.

### BACKGROUND OF THE INVENTION

1. Field of the Invention

The invention relates to a transistor and a fabricating method thereof. More particularly, the invention relates to a thin film transistor and a fabricating method thereof.

2. Description of Related Art

With the attention to environmental protection increasing recently, flat display panels with superior properties such as low consumption power, high space utilization, free of radiation, and high image quality have become the main stream in the market. Common flat displays include liquid crystal displays (LCDs), plasma displays, organic light emitting diode displays (OLEDs), and so on. The most popular LCDs are each mainly constituted by a TFT array substrate, a color filter substrate, and a liquid crystal layer sandwiched in between.

In the conventional TFT array substrate, amorphous silicon (a-Si) TFTs or low temperature polysilicon TFTs are mostly adopted as the switching device in each sub-pixel. Various recent research studies point out that oxide semiconductor TFTs have higher carrier mobility comparing to a-Si TFTs and better threshold voltage (Vth) uniformity comparing to low temperature polysilicon TFTs. As a consequence, oxide semiconductor TFTs have the potential of becoming the key device in the flat displays of the next generation.

In the conventional oxide semiconductor TFTs, the threshold voltage (Vth) of the oxide semiconductor layer is shifted due to the irradiation of a light with short wavelength (i.e. ultraviolet light), thereby affecting the electrical property and reliability of the oxide semiconductor TFTs. Therefore, manufacturers now focus on improving the threshold voltage shift in the oxide semiconductor TFTs caused by the irradiation of the light with short wavelength.

### SUMMARY OF THE INVENTION

The invention is directed to a thin film transistor (TFT) and a fabricating method thereof. The invention is capable of reducing the effect of the light with short wavelength has on the threshold voltage shift in an oxide semiconductor TFT.

The invention is directed to a TFT including a gate, a gate insulator, an oxide semiconductor layer, a source, a drain, and a light barrier. The gate insulator covers the gate. The oxide semiconductor layer is disposed on the gate insulator and located above the gate. The source and the drain are disposed on parts of the oxide semiconductor layer. The light barrier is disposed above the oxide semiconductor layer and includes a first insulator, an ultraviolet shielding layer, and a second insulator. The first insulator is disposed above the oxide semiconductor layer. The ultraviolet shielding layer is disposed on the first insulator. The second insulator is disposed on the ultraviolet shielding layer.

According to an embodiment of the invention, the light barrier is an etch stop layer contacting the source and the drain, where the etch stop layer, the source, and the drain shield the oxide semiconductor layer.

According to an embodiment of the invention, the light barrier is a passivation layer disposed above the oxide semiconductor layer, the source, and the drain.

According to an embodiment of the invention, a material of the first insulator, the ultraviolet shielding layer, and the second insulator is silicon oxide, where an oxygen atom proportion of the ultraviolet shielding layer is lower than an oxygen atom proportion of the first insulator and an oxygen atom proportion of the second insulator.

According to an embodiment of the invention, a material of the first insulator, the ultraviolet shielding layer, and the second insulator is silicon nitride, where a nitrogen atom proportion of the ultraviolet shielding layer is lower than a nitrogen atom proportion of the first insulator and a nitrogen atom proportion of the second insulator.

The invention is further directed to a fabricating method of a TFT, the fabricating method includes the following. A gate is formed on a substrate. A gate insulator is formed on the substrate to cover the gate. An oxide semiconductor layer is formed on the gate insulator and disposed above the gate. A source and a drain are formed on parts of the oxide semiconductor layer. A first insulator, an ultraviolet shielding layer, and a second insulator are formed sequentially on the oxide semiconductor layer as a light barrier.

According to an embodiment of the invention, the step of forming the first insulator, the ultraviolet shielding layer, and the second insulator includes the following. Before forming the source and the drain, a first material layer, a second material layer, and a third material layer are formed sequentially on the gate insulator and the oxide semiconductor layer. The first material layer, the second material layer, and the third material layer on the oxide semiconductor layer are patterned to form the first insulator, the ultraviolet shielding layer, and the second insulator. The light barrier shields parts of the oxide semiconductor layer.

According to an embodiment of the invention, the light barrier, the source, and the drain shield the oxide semiconductor layer.

According to an embodiment of the invention, a material of the first material layer, the second material layer, and the third material layer is silicon oxide, where an oxygen atom proportion of the second material layer is lower than an oxygen atom proportion of the first material layer and an oxygen atom proportion of the third material layer.

According to an embodiment of the invention, the step of forming the first insulator, the ultraviolet shielding layer, and the second insulator includes the following. After forming the source and the drain, the first insulator, the ultraviolet shielding layer, and the second insulator are formed sequentially above the oxide semiconductor layer, the source, and the drain, where the light barrier shields the oxide semiconductor layer, the source, and the drain.

According to an embodiment of the invention, a material of the first insulator, the ultraviolet shielding layer, and the second insulator is silicon oxide, where an oxygen atom proportion of the ultraviolet shielding layer is lower than an oxygen atom proportion of the first insulator and an oxygen atom proportion of the second insulator.

According to an embodiment of the invention, a material of the first insulator, the ultraviolet shielding layer, and the second insulator is silicon nitride, where a nitrogen atom proportion of the ultraviolet shielding layer is lower than a nitrogen atom proportion of the first insulator and a nitrogen atom proportion of the second insulator.

According to an embodiment of the invention, the ultraviolet shielding layer is a silicon-rich layer.

According to an embodiment of the invention, the ultraviolet shielding layer has a thickness ranging from 10 nanometer (nm) to 100 nm.

In light of the foregoing, since the light barrier is disposed and formed comprising the ultraviolet shielding layer in the TFT and the fabricating method of the same in the embodiments of the invention, the chance of the oxide semiconductor layer contacting the ultraviolet light is decreased. Accordingly, effects of the ultraviolet light have on the oxide semiconductor layer can be inhibited.

In order to make the aforementioned and other features and advantages of the invention more comprehensible, several embodiments accompanied with figures are described in detail below.

### BRIEF DESCRIPTION OF THE DRAWINGS

The accompanying drawings are included to provide further understanding, and are incorporated in and constitute a part of this specification. The drawings illustrate embodiments and, together with the description, serve to explain the principles of the invention.

FIGS. 1A to 1J show schematic diagrams of a flow chart for fabricating a thin film transistor (TFT) in one embodiment of the invention.

FIG. 2 is a schematic cross-sectional view illustrating a TFT according to another embodiment of the invention.

### DESCRIPTION OF EMBODIMENTS

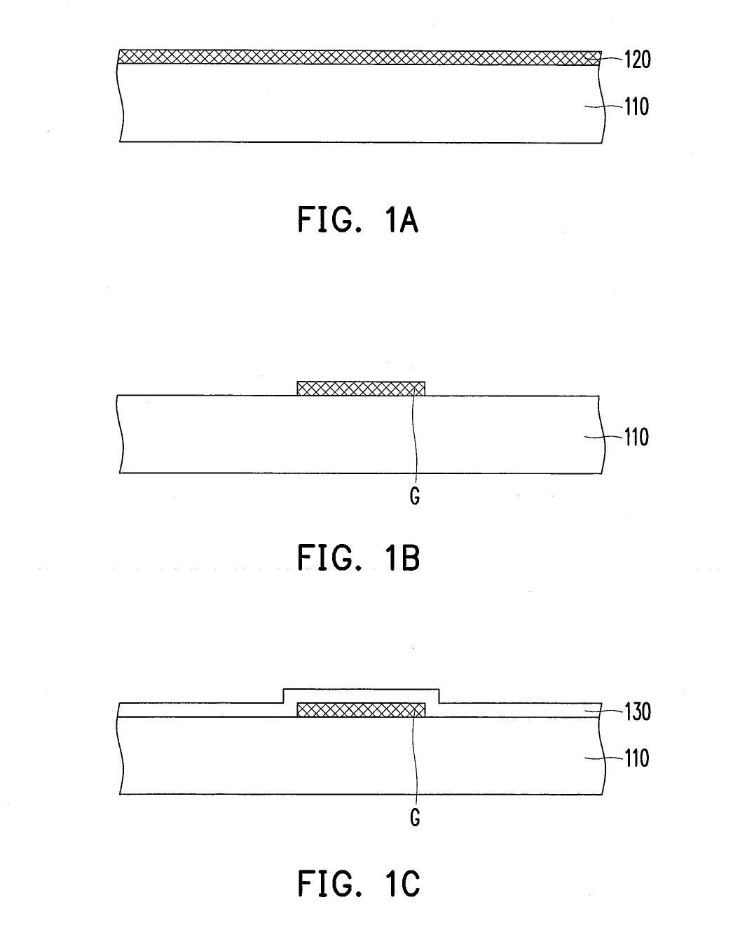

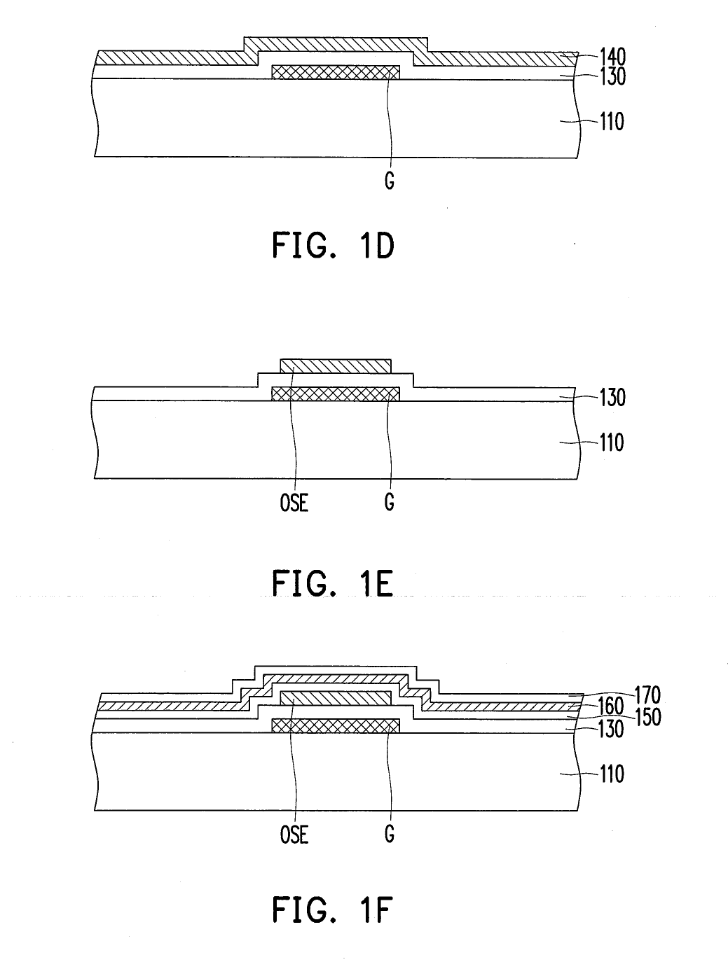

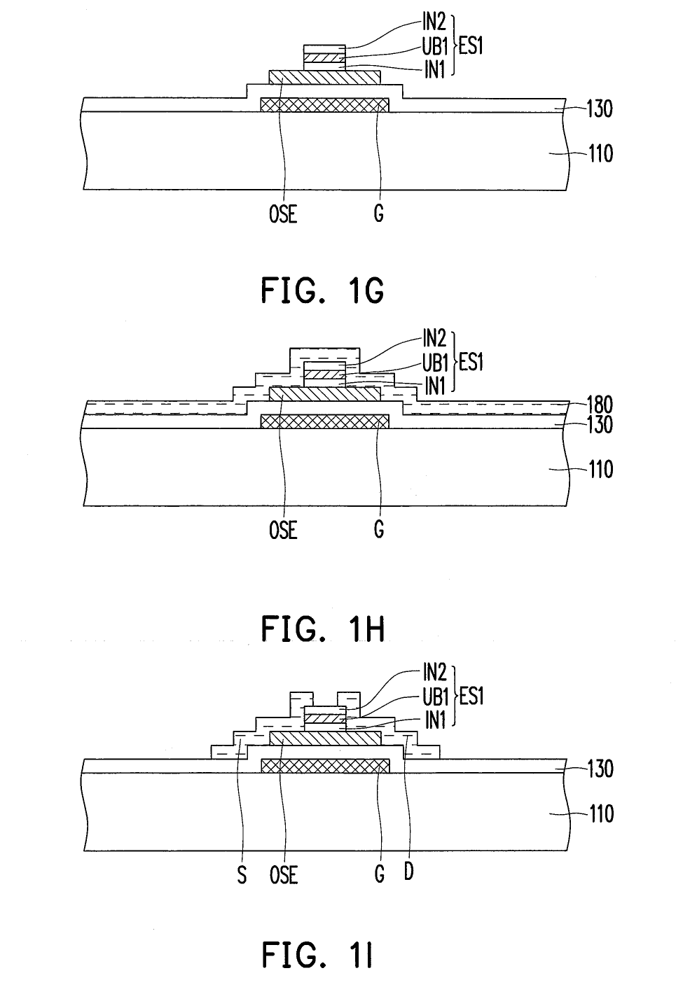

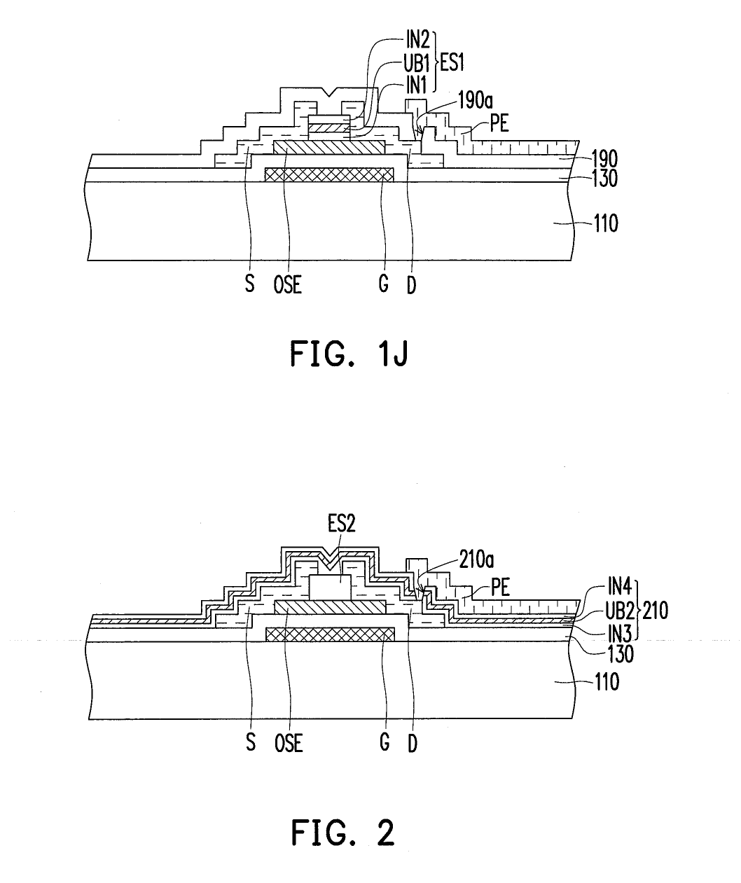

FIGS. 1A to 1J show schematic diagrams of a flow chart for fabricating a thin film transistor (TFT) in one embodiment of the invention. Referring to FIGS. 1A and 1B, firstly, a gate material layer 120 is formed on a substrate 110 and the gate material layer 120 is patterned to form a gate G. In the present embodiment, the gate G (that is, the gate material layer 120) is made of a metal material such as titanium (Ti), molybdenum (Mo), aluminum (Al), or an alloy of the metal materials aforementioned, or a stacked layer of the metal materials above, or other conductive materials. The gate material layer 120 can be formed through a sputtering process and patterned through a photolithography etching process (that is, photoresist coating, photolithography, etching, stripping, and so on) to form the gate G, and the details are omitted hereinafter.

Referring to FIG. 1C, after the gate G is fabricated, a gate insulator 130 is formed on the substrate 110 to cover the gate G. The gate insulator 130, for example, covers the substrate 110 and the gate G entirely. In the present embodiment, the gate insulator 130 is fabricated using silicon oxide (SiO), silicon nitride (SiN), or stacked using the above materials. Herein, the gate insulator 130 is formed by a chemical vapor deposition (CVD) or a physical vapor deposition (PVD).

Referring to FIGS. 1D and 1E, after the gate insulator 130 is formed, an oxide semiconductor material layer 140 is formed on the gate insulator 130. The oxide semiconductor material layer 140 on the gate G is patterned to form an oxide semiconductor layer OSE. In the present embodiment, the oxide semiconductor layer OSE (that is, the oxide semiconductor material layer 140) is made of, for example, indium gallium zinc oxide (IGZO), indium zinc oxide (IZO), indium gallium oxide (IGO), zinc oxide (ZnO), cadmium oxide.germanium oxide (2CdO.GeO₂) or nickel cobalt oxide (NiCo₂O₄). The oxide semiconductor material layer 140 can be formed from a sputtering process and then patterned through a photolithography etching process to form the oxide semiconductor layer OSE, and the details are omitted hereinafter.

Referring to FIGS. 1F and 1G, after the oxide semiconductor layer OSE is formed, a first material layer 150, a second material layer 160, and a third material layer 170 are formed on the gate insulator 130 and the oxide semiconductor layer OSE in sequence. The first material layer 150, the second material layer 160, and the third material layer 170 on the oxide semiconductor layer OSE are patterned to form a first insulator IN1, an ultraviolet shielding layer UB1, and a second insulator layer IN2 respectively. The first insulator IN1, the ultraviolet shielding layer UB1, and the second insulator IN2 are adopted as an etch stop layer ES1. The first insulator IN1, the ultraviolet shielding layer UB1, and the second insulator IN2 shield parts of the oxide semiconductor layer OSE.

In the present embodiment, the first material layer 150, the second material layer 160, and the third material layer 170 can be deposited on surfaces of the gate insulator 130 and the oxide semiconductor layer OSE continuously through sputtering. Moreover, the first material layer 150, the second material layer 160, and the third material layer 170 can be patterned through a photolithography etching process to form the first insulator IN1, the ultraviolet shielding layer UB1, and the second insulator IN2.

For example, the first material layer 150, the second material layer 160, and the third material layer 170 are fabricated with silicon oxide, for instance. When the first material layer 150, the second material layer 160, and the third material layer 170 are formed, the fabrication parameters are adjusted while forming the second material layer 160, so that an oxygen atom proportion of the second material layer 160 is lower than an oxygen atom proportion of the first material layer 150 and an oxygen atom proportion of the third material layer 170. That is, when the oxygen atom proportions of the first material layer 150, the second material layer 160, and the third material layer 170 are respectively X1, X2, and X3, then X1=X3>X2. Therefore, the second material layer 160 is a silicon-rich layer. Here, X1, X2, and X3 are each a positive real number. Generally, a standard proportion of silicon and oxygen is 1:2. That is, a standard chemical formula of silicon oxide is SiO₂. Therefore, an oxygen atom proportion of the first material layer 150 and the third material layer 170 (that is, X1 and X3) is 2, and an oxygen atom proportion of the second material layer 160 (that is, X2) is less than 2. In the present embodiment, the second material layer 160 (that is, the ultraviolet shielding layer UB1) can have a thickness ranging from 10 nanometer (nm) to 100 nm. Since the silicon-rich layer is capable of blocking the ultraviolet light, in other words, the ultraviolet shielding layer UB1 is capable of blocking the ultraviolet light, the etch stop layer ES1 can be deemed as a light barrier for its ability of blocking light. Also, the etch stop layer ES1 is electrical insulated.

Referring to FIGS. 1H and 1I, after the etch stop layer ES1 is formed, a metal conductive layer 180 is formed on the gate insulator 130, the oxide semiconductor layer OSE, and the etch stop layer ES1. The metal conductive layer 180 is patterned to form a source S and a drain D. The source S and the drain D are electrically insulated from each other. The source S and the drain D cover parts of the oxide semiconductor layer OSE respectively and extend toward two opposite sides of the gate G from the top of the etch stop layer ES1. In the present embodiment, the source S and the drain D (that is, the metal conductive layer 180) can be made of a metal material such as Ti, Mo, Al, or an alloy of the metal materials aforementioned (i.e. a Ti-M alloy, a M-Al alloy, a Ti—Al alloy, and the like), or a stacked layer of the metal materials above, or other conductive materials. The metal conductive layer 180 can be formed through a sputtering process and patterned through a photolithography etching process (that is, photoresist coating, photolithography, etching, stripping, and so on) to form the source S and the drain D. However, the details are omitted hereinafter. After the source S and the drain D are fabricated, the TFT in the present embodiment is initially complete.

As shown in FIG. 1I, the TFT in the present embodiment includes the gate G, the gate insulator 130, the oxide semiconductor OSE, the etch stop layer ES1 (identical to a light barrier), the source S, and the drain D. The gate insulator 130 covers the gate G. The oxide semiconductor layer OSE is disposed on the gate insulator 130 and located above the gate G. The etch stop layer ES1, the source S, and the drain D are disposed on parts of the oxide semiconductor layer OSE respectively. The etch stop layer ES1 contacts the source S and the drain D. The etch stop layer ES1, the source S, and the drain D shield the entire oxide semiconductor layer OSE. Since the silicon-rich layer and the metal materials are all capable of blocking the ultraviolet light, the etch stop layer ES1, the source S, and the drain D can block the ultraviolet light effectively to inhibit the effects that the ultraviolet light has on the oxide semiconductor layer OSE (i.e. the shift of the threshold voltage).

Referring to FIG. 1J, in the present embodiment, a passivation layer 190 can be formed on the substrate 110 to cover the etch stop layer ES1, the source S, the drain D, and the gate insulator 130. In the present embodiment, the passivation layer 190 is fabricated using SiO, SiN, or stacked using the above materials. The passivation layer 190 can be formed through a CVD or a PVD.

Further, when the aforementioned TFT is applied in the pixels of the display, a contact opening 190a can be fabricated in the passivation layer 190 and a pixel electrode PE can be fabricated on the passivation layer 190, so that the pixel electrode PE can be electrically connected to the drain D of the TFT through the contact opening 190a.

FIG. 2 is a schematic cross-sectional view illustrating a TFT according to another embodiment of the invention. Referring to FIGS. 1J and 2, the flow chart for fabricating the TFT in the present embodiment is similar to that in FIG. 1J, the difference is that an ultraviolet shielding layer UB2 in the present embodiment is formed on a passivation layer 210 instead of on an etch stop layer ES2. Herein, the passivation layer 210 is deemed as a light barrier and includes a first insulator IN3, the ultraviolet shielding layer UB2, and a second insulator IN4. Since the passivation layer 210 shields the oxide semiconductor layer OSE, the passivation layer 210 is capable of inhibiting the effects the ultraviolet light has on the oxide semiconductor layer OSE effectively.

In the present embodiment, after the source S and the drain D are formed, the first insulator IN3, the ultraviolet shielding layer UB2, and the second insulator IN4 are formed sequentially on the etch stop layer ES2, the source S, the drain D, and the gate insulator 130. The first insulator IN3, the ultraviolet shielding layer UB2, and the second insulator IN4 can be deposited on surfaces of the etch stop layer ES2, the source S, the drain D, and the gate insulator 130 continuously through a CVD or a PVD.

For example, when the first insulator IN3, the ultraviolet shielding layer UB2, and the second insulator IN4 are made of silicon oxide, the fabrication parameters are then adjusted while forming the ultraviolet shielding layer UB2, so that an oxygen atom proportion of the ultraviolet shielding layer UB2 is lower than an oxygen atom proportion of the first insulator IN3 and an oxygen atom of the second insulator IN4. In other words, the ultraviolet shielding layer UB2 is a silicon-rich layer. On the other hand, when the first insulator IN3, the ultraviolet shielding layer UB2, and the second insulator IN4 are made of silicon nitride, the fabrication parameters are also adjusted while forming the ultraviolet shielding layer UB2, so that a nitrogen atom proportion of the ultraviolet shielding layer UB2 is lower than a nitrogen atom proportion of the first insulator IN3 and a nitrogen atom proportion of the second insulator IN4. In other words, the ultraviolet shielding layer UB2 is a silicon-rich layer. That is, when the nitrogen atom proportions of the first insulator IN3, the ultraviolet shielding layer UB2, and the second insulator IN4 are respectively X4, X5, and X6, then X4=X6>X5. Here, X4, X5, and X6 are each a positive real number. Generally, a standard proportion of silicon and nitrogen is 3:4 (that is, 1:1.33). That is, a standard chemical formula of silicon oxide is Si₃O₄. Therefore, a nitrogen atom proportion of the first insulator IN3 and the second insulator 1N4 (that is, X4 and X6) is 1.33, and an nitrogen atom proportion of the ultraviolet shielding layer UB2 (that is, X5) is less than 1.33.

In addition, a contact opening 210a can be fabricated in the passivation layer 210 in the present embodiment and a pixel electrode PE can be fabricated on the passivation layer 210, such that the pixel electrode PE can be electrically connected to the drain D of the TFT through the contact opening 210a.

In summary, the ultraviolet shielding layer is formed in the etch stop layer or the passivation layer in the TFT and the fabricating method thereof in the embodiments of the invention. In other words, when forming the etch stop layer or the passivation layer, the silicon-rich layer can be formed in the etch stop layer or the passivation layer through the adjustment of the fabrication parameters. Accordingly, effects of the ultraviolet light have on the oxide semiconductor layer can be inhibited.

It will be apparent to those skilled in the art that various modifications and variations can be made to the structure of the disclosed embodiments without departing from the scope or spirit of the invention. In view of the foregoing, it is intended that the invention cover modifications and variations of this invention provided they fall within the scope of the following claims and their equivalents.

What is claimed is:

1. A thin film transistor, comprising:
a gate;
a gate insulator covering the gate;
an oxide semiconductor layer disposed on the gate insulator and located above the gate;
a source and a drain disposed on a part of the oxide semiconductor layer; and
a light barrier disposed above the oxide semiconductor layer, the light barrier comprising:
a first insulator disposed above the oxide semiconductor layer;
an ultraviolet shielding layer disposed on the first insulator; and
a second insulator disposed on the ultraviolet shielding layer.

2. The thin film transistor as claimed in claim 1, wherein the ultraviolet shielding layer is a silicon-rich layer.

3. The thin film transistor as claimed in claim 2, wherein the light barrier is an etch stop layer contacting the source and the drain, and wherein the etch stop layer, the source, and the drain shield the oxide semiconductor layer.

4. The thin film transistor as claimed in claim 3, wherein materials of the first insulator, the ultraviolet shielding layer, and the second insulator are silicon oxide, and wherein an oxygen atom proportion of the ultraviolet shielding layer is lower than an oxygen atom proportion of the first insulator and an oxygen atom proportion of the second insulator.

5. The thin film transistor as claimed in claim 2, wherein the light barrier is a passivation layer disposed above the oxide semiconductor layer, the source, and the drain.

6. The thin film transistor as claimed in claim 5, wherein a material of the first insulator, the ultraviolet shielding layer, and the second insulator is silicon oxide, wherein an oxygen atom proportion of the ultraviolet shielding layer is lower than an oxygen atom proportion of the first insulator and an oxygen atom proportion of the second insulator.

7. The thin film transistor as claimed in claim 5, wherein a material of the first insulator, the ultraviolet shielding layer, and the second insulator is silicon nitride, wherein a nitrogen atom proportion of the ultraviolet shielding layer is lower than a nitrogen atom proportion of the first insulator and a nitrogen atom proportion of the second insulator.

8. The thin film transistor as claimed in claim 2, wherein the ultraviolet shielding layer has a thickness ranging from 10 nanometer (nm) to 100 nm.

9. A method of fabricating a thin film transistor, comprising:
forming a gate on a substrate;
forming a gate insulator on the substrate to cover the gate;
forming an oxide semiconductor layer on the gate insulator disposed above the gate;
forming a source and a drain on a part of the oxide semiconductor layer; and
forming a first insulator, an ultraviolet shielding layer, and a second insulator sequentially above the oxide semiconductor layer as a light barrier.

10. The method of fabricating the thin film transistor as claimed in claim 9, wherein the step of forming the first insulator, the ultraviolet shielding layer, and the second insulator comprises:
before forming the source and the drain, forming a first material layer, a second material layer, and a third material layer sequentially on the gate insulator and the oxide semiconductor layer; and
patterning the first material layer, the second material layer, and the third material layer on the oxide semiconductor layer to form the first insulator, the ultraviolet shielding layer, and the second insulator, wherein the light barrier shields a part of the oxide semiconductor layer.

11. The method of fabricating the thin film transistor as claimed in claim 10, wherein the light barrier, the source, and the drain shield the oxide semiconductor layer.

12. The method of fabricating the thin film transistor as claimed in claim 11, wherein a material of the first material layer, the second material layer, and the third material layer is silicon oxide, wherein an oxygen atom proportion of the second material layer is lower than an oxygen atom proportion of the first material layer and an oxygen atom proportion of the third material layer.

13. The method of fabricating the thin film transistor as claimed in claim 9, wherein the step of forming the first insulator, the ultraviolet shielding layer, and the second insulator comprises:
after forming the source and the drain, forming the first insulator, the ultraviolet shielding layer, and the second insulator sequentially above the oxide semiconductor layer, the source, and the drain, wherein the light barrier shields the oxide semiconductor layer, the source, and the drain.

14. The method of fabricating the thin film transistor as claimed in claim 13, wherein a material of the first insulator, the ultraviolet shielding layer, and the second insulator is silicon oxide, wherein an oxygen atom proportion of the ultraviolet shielding layer is lower than an oxygen atom proportion of the first insulator and an oxygen atom proportion of the second insulator.

15. The method of fabricating the thin film transistor as claimed in claim 13, wherein materials of the first insulator, the ultraviolet shielding layer, and the second insulator are silicon nitride, wherein a nitrogen atom proportion of the ultraviolet shielding layer is lower than a nitrogen atom proportion of the first insulator and a nitrogen atom proportion of the second insulator.

16. The method of fabricating the thin film transistor as claimed in claim 9, wherein the ultraviolet shielding layer is a silicon-rich layer.

17. The method of fabricating the thin film transistor as claimed in claim 16, wherein the ultraviolet shielding layer has a thickness ranging from 10 nm to 100 nm.
